(19) United States
(12) Patent Application Publication
(10) Pub. No.: US 2024/0359822 A1
(43) Pub. Date: Oct. 31, 2024

(54) VISION-BASED APPROACH AND LANDING SYSTEM

(71) Applicant: United States of America as Represented by the Administrator of NASA, Washington, DC (US)

(72) Inventors: Evan Tatsuaki Kawamura, Mililani, HI (US); Corey A. Ippolito, San Jose, CA (US); Thomas Jan Jozef Lombaerts, Sunnyvale, CA (US); Keerthana Kannan, Sunnyvale, CA (US)

(21) Appl. No.: 18/395,461

(22) Filed: Dec. 22, 2023

Related U.S. Application Data
(60) Provisional application No. 63/476,945, filed on Dec. 22, 2022.

(51) Int. Cl. B64D 45/08; G05D 1/246; G05D 1/654; G05D 109/20; G05D 111/10; G06F 30/15; G06T 7/277; G06T 7/73

(52) U.S. Cl. CPC B64D 45/08; G05D 1/246; G05D 1/6545; G06F 30/15; G06T 7/277; G06T 7/74; G05D 2109/20; G05D 2111/10; G06T 2207/10032; G06T 2207/20061; G06T 2207/30204; G06T 2207/30252

(57) ABSTRACT

A vision-based navigation method that does not depend on GPS signal for landing AAM aircraft. The Vision-Based Approach and Landing System (VALS) uses images captured from a camera for Advanced Air Mobility (AAM) approach and landing in GPS-denied environments, which offers a potential Alternative Position, Navigation, and Timing (APNT) solution. VALS utilizes a computer vision algorithm called Coplanar Pose from Orthography and Scaling with Iterations (COPOSIT) to estimate the position and orientation of the camera based on coplanar features. VALS also includes an extended Kalman filter that uses IMU measurements in a prediction step and the COPOSIT estimation results in a correction element. Combining IMU with vision creates a sensor fusion navigation solution for GPS-denied environments.

### PRIORITY

The present application claims priority to U.S. Provisional Application 63/476,945, titled “Vision-based Approach and Landing System,” filed Dec. 22, 2022, which is herein incorporated by reference in its entirety.

### ORIGIN OF INVENTION

The invention described herein was made in the performance of work under a NASA contract and by (an) employee(s) of the United States Government and is subject to the provisions 51 U.S.C. § 20135 (b), Public Law 111-314, § 3 (124 Stat. 3330, 51 U.S.C. Chapter 201), and may be manufactured and used by or for the Government for governmental purposes without the payment of any royalties thereon or therefore.

### FIELD

The present invention relates to a landing system and, specifically, to a method and system for landing an aircraft using a vision-based navigation method.

### BACKGROUND

Advanced Air Mobility (AAM) aircraft need accurate navigation solutions in all types of environments. Conventional GPS-based solutions for approach and landing may not be applicable for AAM operations. For example, GPS degradation occurs in urban environments since line of sight to GPS satellites may be blocked by buildings or other obstructions, making reliance on GPS for landing unreliable or unavailable. A similar problem occurs in heavily forested areas or areas in high mountains or deep canyons. As another example, narrow visual navigation aids like the glideslope and localizer do not offer effective alternative incoming landing angles at vertiports (landing areas for vertically landing AAM.) Consequently, it is difficult to maintain a consistent glidepath around buildings since the aircraft must fly around buildings.

As another example, the GPS software in an aircraft may be blocked, jammed, or inoperative, making reliance on GPS ineffective. GPS spoofing can also occur and will cause navigation and safety problems, which makes crashes more likely.

### BRIEF DESCRIPTION OF THE DRAWINGS

The invention may best be understood by referring to the following description and accompanying drawings that are used to illustrate embodiments of the invention. In the drawings:

FIG. 1 shows an overview of an environment in which an AAM aircraft might operate.

FIG. 2 is a diagram of a Vision-based Approach and Landing System (VALS), according to some embodiments of the invention.

FIGS. 3a and 3b show the output results of two possible methods of feature detection of the VALS shown in FIG. 2.

FIGS. 4a and 4b show diagrams of an embodiment of an extended Kalman filter (EKF) of FIG. 2 and its inputs.

FIG. 4c shows another embodiment of the extended Kalman filter of FIG. 2 that does not receive input from the Coplanar Pose from Orthography and Scaling with Iterations (COPOSIT) method when input from the COPOSIT method is not available.

FIG. 5 shows an example of conventional FAA landing systems.

FIG. 6 shows examples of the world coordinate system (WCS) axes, the vehicle coordinate system (VCS) axes, and the camera coordinate system (CCS) axes.

FIGS. 7a, 7b, and 7c are charts showing example results from an embodiment of the EKF for, respectively, estimates of position, estimates of velocity, and estimates of orientation (Euler angles).

FIG. 8 is a block diagram of one embodiment of a computer system that may be used with the present invention.

### DETAILED DESCRIPTION

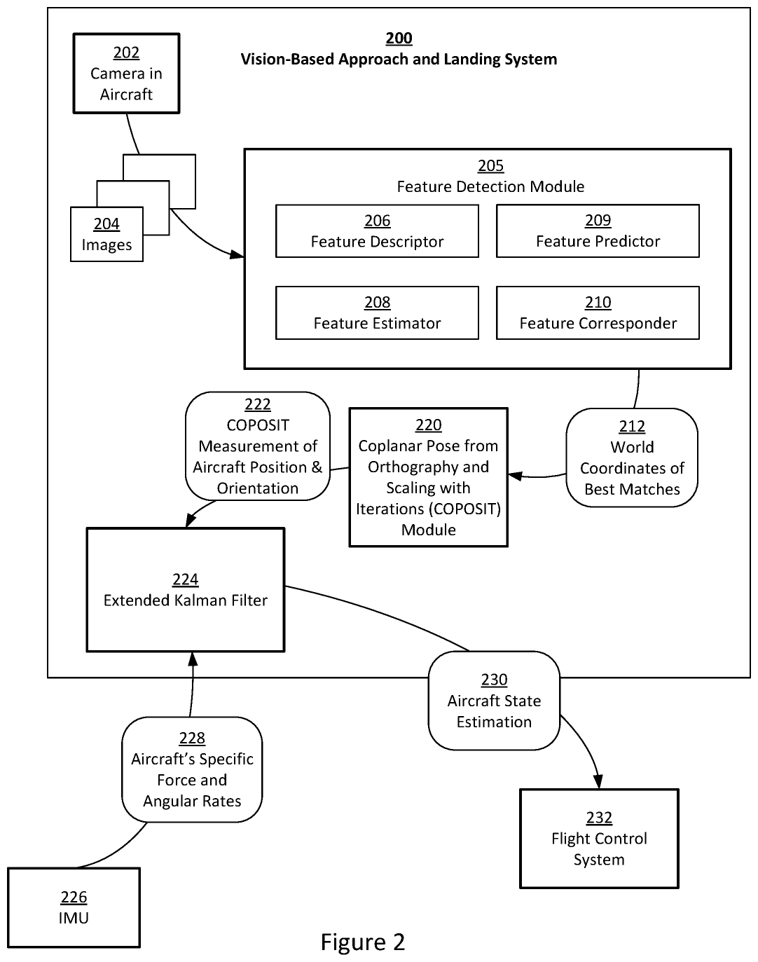

As discussed above, there are certain situations when landing an AAM aircraft is required to be performed without assistance from GPS data. AAM aircraft flying among tall buildings of similar height, narrow canyons, etc., may affect the ability of the AAM aircraft to effectively use GPS to access a landing area. According to some embodiments of the present invention, airport/heliport/vertiport lighting systems, cones, and other markers provide a baseline for visual navigation aids, which will assist AAM aircraft during approach and landing. Incorporating a vision-based navigation method without depending on GPS provides a potential Alternative Position, Navigation, and Timing (APNT) solution for AAM aircraft in environments where GPS is not available. In an embodiment, position, velocity, and orientation of the aircraft is determined without access to GPS. See overview of FIG. 2 below.

With reference to FIG. 2, the described embodiments apply the computer vision method, Coplanar Pose from Orthography and Scaling with Iterations (COPOSIT), which runs in near real-time. The COPOSIT method is a method for the computation of the position and orientation of a camera with respect to a known object using four or more coplanar feature points. The accuracy for COPOSIT tends to increase when the number of coplanar points (e.g., fiducials, landmarks, or landing lights) increase and when they are spaced out. Coplanar points such as landing lights, fiducials, and indicators such as cones or landmarks are sometimes referred to herein as runway indications.

Advanced Air Mobility (AAM) or Urban Air Mobility (UAM) aircraft (e.g., drones and other unmanned aerial vehicles (UAVs), and electric vertical takeoff and landing (VTOL) aircraft) have the potential to benefit from embodiments of the present invention. Commercial aircraft with downward-facing cameras may also apply this approach and incorporate a landing system based on the landing lights or fiducials on the runway. Airports, heliports, and vertiports with landmarks or landing lights or fiducials can directly apply these embodiments to assist incoming aircraft during approach and landing.

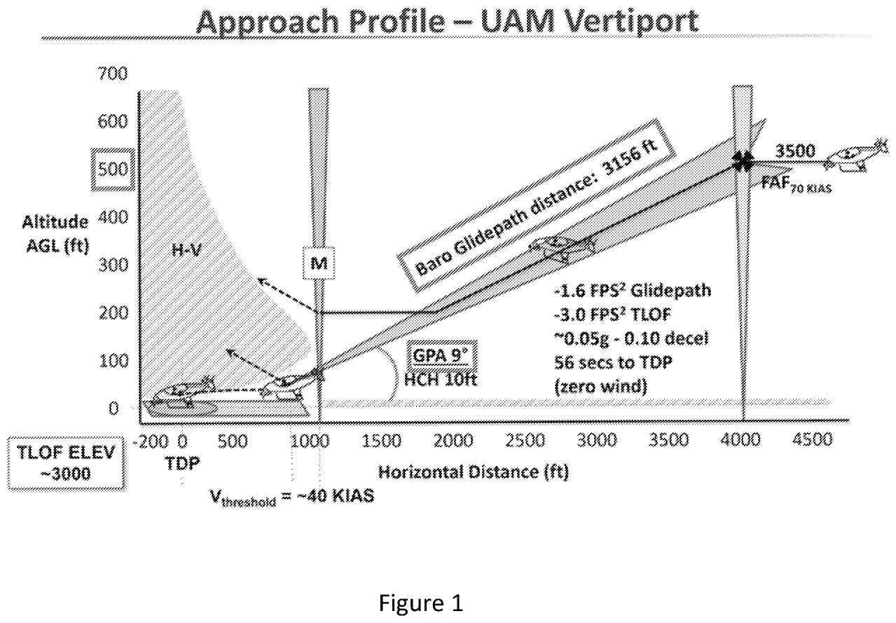

FIG. 1 shows a sample environment in which an aircraft might safely approach and land at an urban air mobility (UAM) vertiport. A vertical axis shows altitude above ground level (agl) in feet, while a horizontal axis shows horizontal distance in feet. In the figure, the altitude agl is 500 ft above the landing area (shown as a rectangle on ground), the glidepath angle (GPA) is 9°, the glidepath distance is about 3000 ft (shown as triangles between the aircraft and the ground). It will be understood that various types of landing areas have different safety margins and desirable approach paths. It will also be understood that the aircraft's flight control system needs to know its position, velocity, and orientation to land safely. As discussed above, if a GPS signal is not available, it is difficult to know precise position, orientation, and velocity in conventional systems.

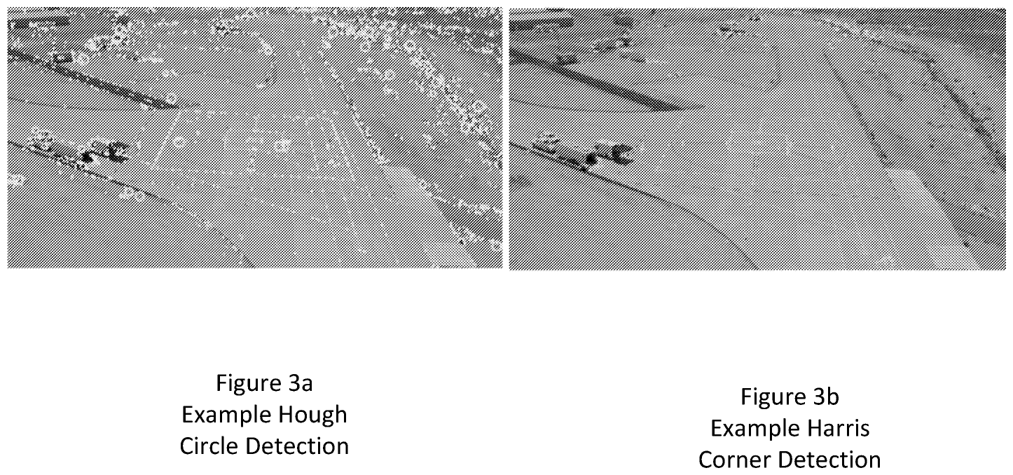

FIGS. 3a and 3b show examples of fiducials such as heliport markings and cones, different views of which will be visible to a landing aircraft at various times during its descent. During descent, an aircraft using described embodiments of the invention is generally moving quickly forward and downwards, and is detecting fiducials in front of it within an area capturable by its cameras in one embodiment. For example, fiducials may pass outside of horizontal and vertical visual range of a camera as the aircraft gets closer to the runway. As another example, fiducials may be temporarily obscured by clouds, building, the aircraft body, etc., as the aircraft continues its descent. There could also be smudges or precipitation on the camera lens, which would degrade detection. In addition to cameras capturing images from visible light, other embodiments could use, for example, radar or LIDAR, but each of these approaches has disadvantages. Radar encounters electromagnetic noise in its signal, and emits radiation and noise to others, requiring radar to operate at low levels for safety concerns. LIDAR could be used if the laser beams are at low power, also for safety concerns. Cameras are good sensors to use because they do not emit any radiation, lasers, or noise into the environment.

FIG. 2 is a diagram of a Vision-based Approach and Landing System (VALS) 200 employed by some embodiments of the invention. One purpose of VALS is to provide AAM aircraft with an Alternative Position, Navigation, and Timing (APNT) solution for approach and landing without relying on GPS. VALS 200 operates on multiple images 204 obtained by the aircraft as the aircraft performs its descent. In one embodiment, images 204 are obtained at a rate of 30 frames per second (fps) from camera 202, which is attached to or associated with an aircraft. In an example embodiment, the system uses one fixed-angle camera per aircraft. Camera 202 is angled downward and forwards towards the landing zone. Next, in some embodiments, the images are processed in feature detection module 205. Feature detection module 205 includes a feature descriptor 206, a feature estimator 208, a feature predictor 209, and a feature corresponder 210. Feature descriptor 206 is applied to each of images 204 to detect landmark locations in images 204. In one embodiment, these landmark locations are known ahead of time and stored in a memory for use by the system. As discussed below, feature descriptor 206 may use Hough circles, Harris corner detection, or any other appropriate feature detection method. In certain embodiments, localized data can be used to improve on feature detection based on known landmarks, guidelines, fiducials, or geometrical patterns at runways, heliports, and vertiports. In comparison, typical vision-based navigation methods obtain ground truth or global position estimation by combining visual odometry with a priori maps or using multiple reference points with known latitude and longitude in each map.

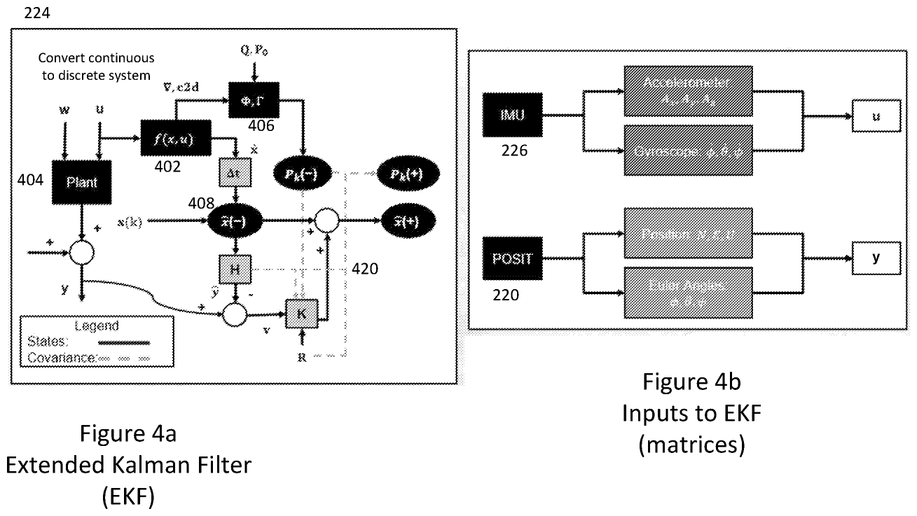

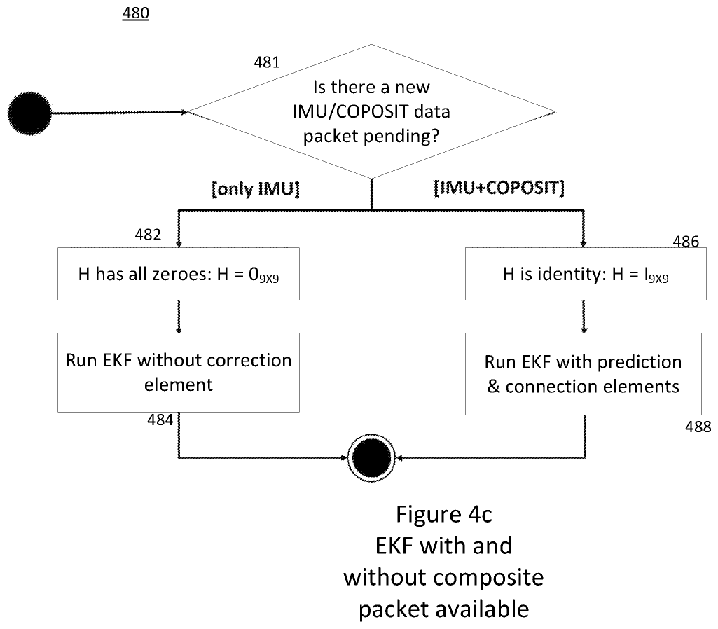

Next, detected landmark locations, as identified by their pixel coordinates, are estimated in an image to produce a set of estimated landmark locations 208 for the image. Predicted landmark locations, which in some embodiments are landmark locations predicted to be in the aircraft's landing area, and which are stored ahead of time on the aircraft's onboard computer, are predicted in terms of pixel coordinates of an image to produce a set of predicted landmark locations 209 for a landing area expected to be captured in images 204. Feature corresponder 210 then compares the estimated landmark locations 208 and predicted landmark locations 209 in pixel coordinates to find the estimated landmark features that closely match the predicted landmark features to determine a correspondence between them. These best matches are matched to the inertial world coordinates of the landmarks, and world coordinates of best matches 212 are outputted. World coordinates of best matches 212 are inserted into the Coplanar Pose from Orthography and Scaling with Iterations (COPOSIT) module 220 that uses the COPOSIT method to estimate the camera position and orientation relative to at least four coplanar points. Aircraft position and orientation are estimated from the estimated camera position and orientation by transformation matrices, which produces a COPOSIT measurement of the aircraft position and orientation 222. As shown in FIGS. 2 and 4a, COPOSIT measurement 222 is fed into the correction element 420 of an extended Kalman filter (EKF) 224, and the onboard IMU (inertial measurement unit) 226 measurements such as aircraft's specific force and angular rates 228 are used in the EKF's prediction step. The correction element 420 in EKF 224 has four parts: (1) v (goes into K), (2) K (gray box), (3) the white circle between \hat{x}(−) and \hat{x}(+), and (4) Pₖ (+). IMU 226 is an electronic device in the aircraft that measures and reports the aircraft's specific force and angular rates 228, using any appropriate combination of accelerometers, gyroscopes, magnetometers, etc. Angular rates are sometimes referred to as body rates. In some embodiments, no magnetometer is present. Using COPOSIT measurement 222 and the aircraft's specific force and angular rates 222 from IMU 226, EKF 224 determines state estimation 230 of the aircraft, which is outputted to the aircraft's flight control system 232. State 230 is used by flight control system 232 to control the aircraft's landing operation. State 230 includes the corrected estimated position, corrected estimated velocity, and corrected estimated orientation of the aircraft. In one embodiment, the IMU measurements, COPOSIT pose measurements, and the EKF time steps all use a same timestep (for example 0.01 seconds) to keep time synchronization simple.

In one embodiment, the operations referenced in FIG. 2 runs on a system onboard an aircraft in near real time. As discussed below, if COPOSIT module 220 cannot produce data fast enough for EKF 224, the measurement data normally received by EKF 224 from the COPOSIT module 220 is zeroed when no data is available, and the EKF proceeds without position and attitude data from COPOSIT module 220. In an example embodiment, EKF 224 may run at 100 Hz, while the COPOSIT method runs at 10-20 Hz on COPOSIT module 220. Other speeds may be used depending on the implementation technology. As another example, COPOSIT module 220 may not be able to obtain four coplanar points due to obstructions in the visual input data and thus cannot provide data to EKF 224. Another scenario when COPOSIT module 220 may not be able to obtain four coplanar points is when the landmarks appear clustered together when the camera is very far from the landing zone, so numerous points may appear to be combined into one or two points.

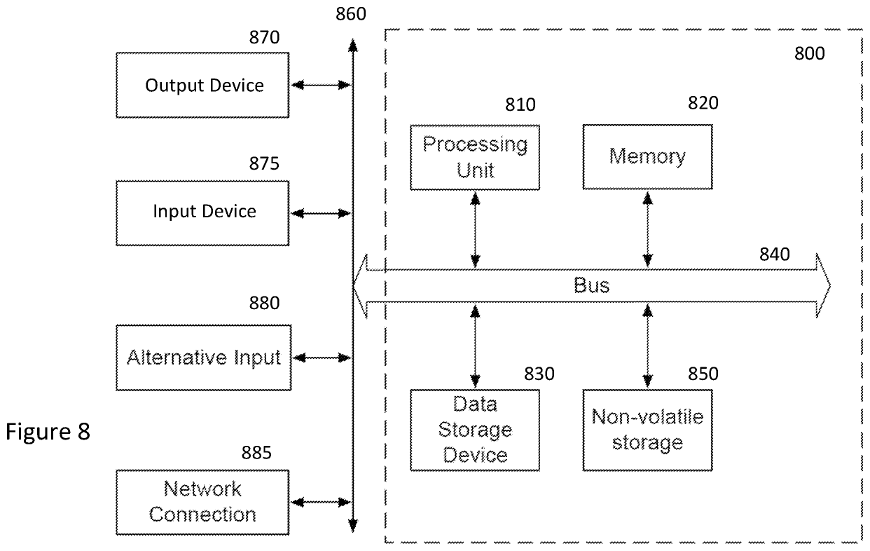

It will be understood that the method of FIG. 2 can be performed by a wide variety of hardware and/or software systems. For example, the method can be performed by the processing unit 810 of FIG. 8 performing instructions stored in a memory. As another example, the method can be performed in hardware, or by a combination of hardware and software. As another example, the method can be performed by a simulator to simulate aircraft flight using computer-generated terrain and fiducials, etc., and/or generated images representing the fiducials, terrain, etc. Images 204 of FIG. 2 are conventional digital camera images stored in memory. In one embodiment, camera 202 generates images of 4000×2000 pixels. Other embodiments may use images of 1920×1080 pixels, images of 4096×2160 pixels, or any other appropriate image size. Testing for an embodiment of this system was performed by obtaining real world telemetry data and videos from a drone flight test at a helipad at the NASA Armstrong Flight Research Center (AFRC). This real-world data was used to test and simulate an embodiment of the invention. The telemetry data used three frames: inertial world coordinates in East North Up, vehicle coordinates, and camera coordinates. The telemetry data included a state vector with inertial position and velocity with the roll, pitch, yaw Euler angles. The NGA (National Geospatial Intelligence Agency) provided the WGS84 latitude and longitude coordinates for the helipad markings with a horizontal accuracy of 0.02 m and a vertical accuracy of 0.1 m. Cones were placed on the helipad, the cone locations coinciding with the concrete square intersection points in the concrete of the helipad to yield precise, repeatable locations.

FIGS. 3a and 3b show the output results of two possible methods of feature detection. In an aircraft landing situation, examples of features would include landing lights, fiducials, or landing cones (in a smaller airport/heliport). Thus, either identifying circles or corners in an image from the aircraft will be useful in identifying these features.

For identifying circles in an image, FIG. 3a shows an example result of Hough circle detection, which is described, for example, in Yuen et al, “Comparative Study of Hough Transform Methods for Circle Finding,” Image and Vision Computing, Vol. 8, Issue 1, February 1990, pages 71-77, which is herein incorporated by reference in its entirety. Hough circle detection is an implementation of the circle Hough Transform (CHT), which is a conventional feature extraction technique used in digital image processing for detecting circles in imperfect images. The circle candidates are produced by “voting” in the Hough parameter space and then selecting local maxima in an accumulator matrix. Hough circle detection has been observed to work well for circular markers such as lights.

For identifying corners in an image, FIG. 3b shows an example result of Harris corner detection, which is described, for example, in Harris and Stephens, “A Combined Corner and Edge Detector,” Alvey Vision Conference, Vol. 15 (1988), which is herein incorporated by reference in its entirety. Harris corner detection has been observed to work well for detecting markers such as cones with sharper edges than circles. It will be understood that any appropriate method of feature detection, implemented by hardware or software, can be used with various embodiments. Which feature detection method is used may depend, for example, on the type of features expected to be observed.

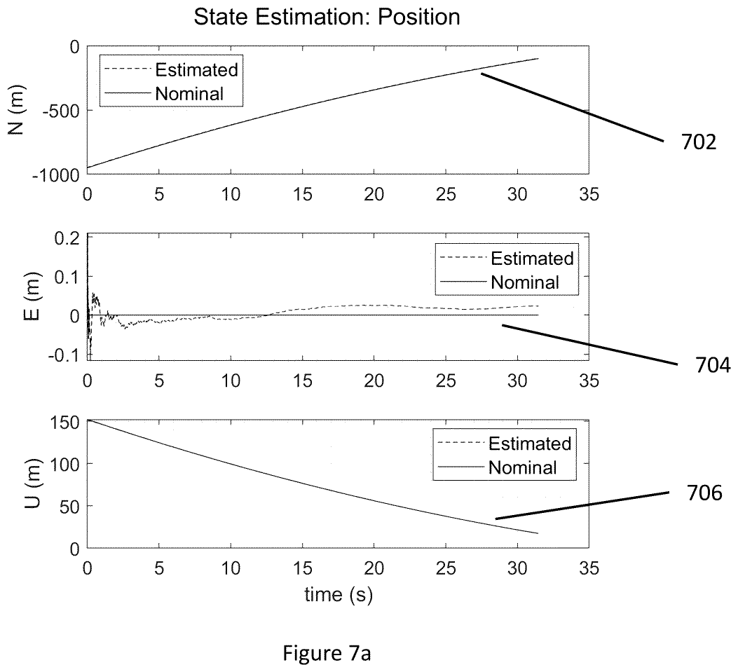

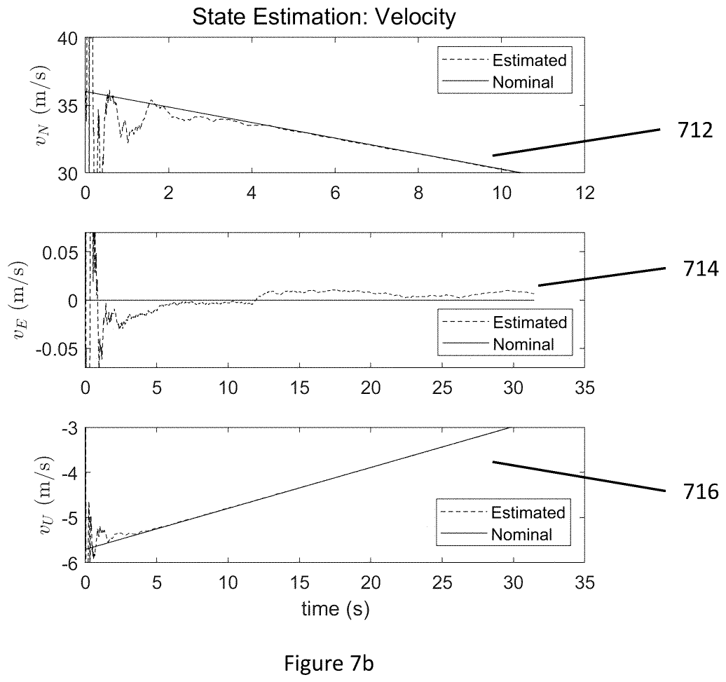

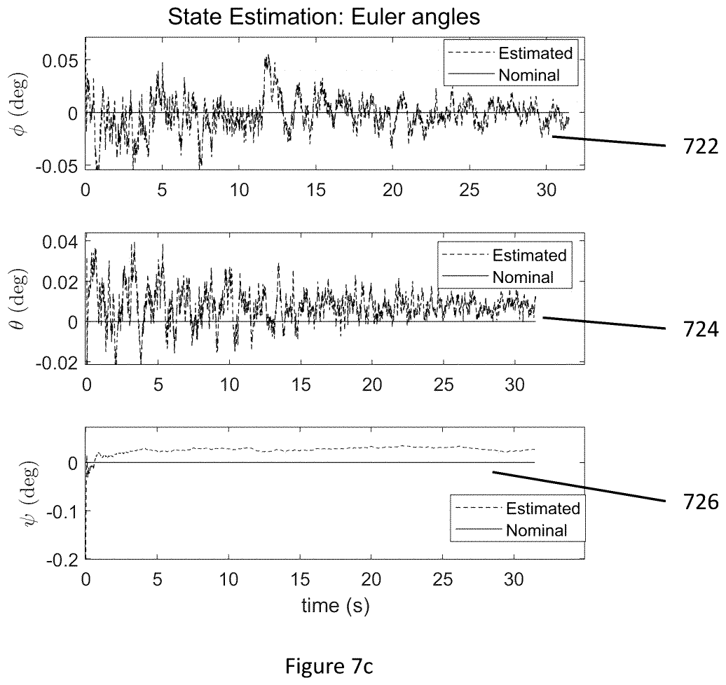

COPOSIT module 220 determines position and orientation of camera 202 from a single image captured by the camera given at least four coplanar points, thereby also determining the position and orientation of the aircraft onto which camera 202 is mounted. Coplanar points are points that lie within the same plane. The COPOSIT module 220 replaces the function of a GPS in a conventional system. COPOSIT relies on visual data and does not require receiving or sending an electromagnetic signal as a GPS system does. In addition, the COPOSIT module 220 gives an attitude (a/k/a orientation) of the aircraft (for example, rotation and translation). An example of the COPOSIT method executed by the COPOSIT module 220 is discussed in Oberkampf, D., DeMenthon, D. F., and Davis, L. S., “Iterative Pose Estimation Using Coplanar Feature Points,” Computer Vision and Image Understanding, Vol. 63, No. 3, 1996, pp. 495-511, the entirety of the paper being incorporated herein by reference. See Figure 7 of Oberkampf, The POSIT algorithm for coplanar scene points. The COPOSIT method is open sourced and code implementing the method is available on http://www.daniel.umiacs.io/Site_2/Code.html, which is herein incorporated by reference in its entirety.

FIGS. 4a and 4b show diagrams of an embodiment of an extended Kalman filter (EKF) 224, as shown in FIG. 2, and its inputs.

FIG. 4a shows the EKF design with solid lines for states and dashed lines for covariances.

This section discusses the state vector, coordinate frames, kinematics, and dynamics for, for example, AAM aircraft and the EKF of FIG. 4a. It will be understood that all matrices and vectors discussed herein are stored in a memory, such as that shown in FIG. 8 and that instructions for all processing are executed by a processor such as that in FIG. 8. In some embodiments, processing is performed in real time at a rate of many times per second. Thus, computation of state 230 must be performed by a computer at a rate faster than a human being could perform matrix multiplications by hand in order to achieve the objective to safely land an aircraft using images captured at 30 fps from camera 202.

### A. State Vector

The state vector 230 of the AAM aircraft is defined as:

$$s = {[ \begin{matrix}E & N & U & vN & vE & vU & ϕ & θ & ψ\end{matrix} ]}^{T} .$$

The state vector s decomposes to three vectors:

$$s = [ \begin{matrix}p & v & Θ\end{matrix} ] ,$$

where each of them is defined as

$$p = [ \begin{matrix}E & N & U\end{matrix} ] , v = \begin{matrix}h & {v}_{x} & {v}_{y} & {v}_{z}\end{matrix} ] , Θ = [ \begin{matrix}ϕ & θ & ψ\end{matrix} ] .$$

The vector p is in East, North, and Up (ENU) coordinates in the inertial frame, fixed on the ground at the helipad landing site. The translational velocities in ν are in the inertial frame. The Euler angles are the roll, pitch, and yaw angles (ϕ, θ, Ψ).

### B. Coordinate Frames

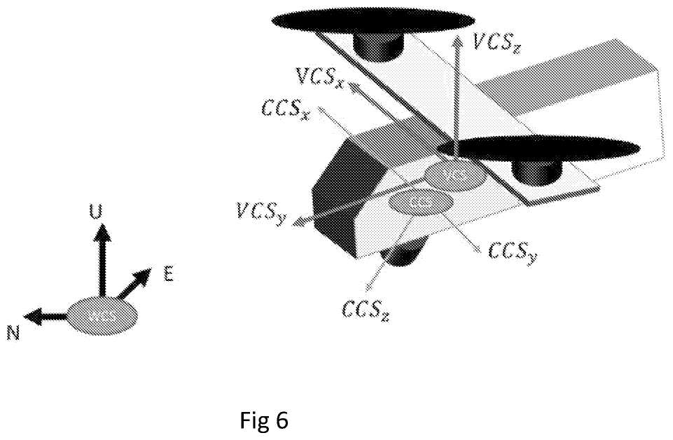

The world coordinate system (WCS) is an inertial frame fixed on the ground in which gravity is pointing in the negative U-direction, i.e., down. The vehicle coordinate system (VCS) is on the body frame on the aircraft such that the x-axis points right, the y-axis points forward, and the z-axis points up in the same direction as the motor axes. The camera coordinate system (CCS) has the camera fixed to the aircraft's body, angled down, and pointed in the positive z-axis. Its x-axis points right like in VCS, and the y-axis points down and behind the aircraft. FIG. 6 shows the WCS axes denoted by E, N, U, the VCS axes denoted by VCSₓ, VCS_{y}, VCS_{z}, and the CCS axes denoted by CCSₓ, CCS_{y}, CCS_{z}. A rotation matrix following the (3-1-2) sequence is applied to rotate the aircraft from the inertial frame to the body frame.

### C. Euler Angles

Embodiments of this invention utilizes the (3-1-2) sequence of the direction cosine matrix and rotates the inertial frame to the body frame through the Euler angles:

$$R = {R}_{y} ( ϕ ) {R}_{x} ( θ ) {R}_{z} ( ψ ) = [ \begin{matrix}- s ψ s θ s ϕ + c ϕ c ψ & s ϕ s θ c ψ + c ϕ s ψ & - s ϕ c θ \\ - c θ s ψ & c θ c ψ & s θ \\ c ϕ s θ s ψ + s ϕ c ψ & - c ϕ s θ c ψ + s ϕ s ψ & c ϕc θ\end{matrix} ] .$$

where cθ and se denote cos θ and sin θ respectively. R_{z} (ω) is the rotation matrix around the z-axis by ω, Rₓ(θ) is the rotation matrix around the once rotated x-axis by θ, and R_{y}(ϕ) is the rotation matrix around the twice rotated y-axis by ϕ. The relationship between the angular velocity and Euler angular rates for the (3-1-2) direction cosine matrix sequence is:

$$Ω = [ \begin{matrix}0 & cos ϕ & - cos θsin ϕ \\ 1 & 0 & sin θ \\ 0 & sin ϕ & cos θcos ϕ\end{matrix} ] \dot{Θ}$$

such that Ω=[r q p]^{T} and Θ=[Ψ θ ϕ]_{T}.

### D. Position and Velocity

Transposing the direction cosine matrix of the prior subsection relates the time derivative of the inertial position vector and the body frame's velocity vector:

$$[ \begin{matrix}{v}_{N} \\ {v}_{E} \\ {v}_{U}\end{matrix} ] = [ \begin{matrix}- s ψ s θ s ϕ + c ϕ c ψ & - c θ s ψ & c ϕ s θ s ψ + s ϕ c ψ \\ s ϕ s θ c ψ + c ϕ s ψ & c θ c ψ & - c ϕ s θ c ψ + s ϕ s ψ \\ - s ϕ c θ & s θ & c ϕ c θ\end{matrix} ]$$

### E. Translational Dynamics

The general aircraft translational dynamic equations are:

$$\begin{matrix}{F}_{x} = m ( \dot{u} + qw - rv ) + mg sin θ \\ {F}_{y} = m ( \dot{v} + ru - pw ) + mg cos θsin ϕ \\ {F}_{z} = m ( \dot{w} + pv - qu ) + mg cos θcos ϕ ,\end{matrix}$$

in which m is the mass, g is the acceleration due to gravity, Fₓ, F_{y}, F_{z} are the aerodynamic forces, u, v, w are the velocities in the body frame, p, q, r are the angular velocities in the body frame, and ϕ, θ, Ψ are the roll, pitch, and yaw Euler angles. Modeling specific forces as accelerometer measurements at the aircraft's center of gravity measure the specific aerodynamic forces:

$${F}_{x} = {A}_{x} m , {F}_{y} = {A}_{y} m , {F}_{z} = {A}_{z} m$$

such that Aₓ, A_{y}, A_{z} are the accelerometer measurements at the aircraft's center of gravity. Inserting Eq. (7) into Eq. (8) yields:

$$\begin{matrix}\dot{u} = {A}_{x} - g sin θ - qw + rv , \\ \dot{v} = {A}_{y} - g cos θsinϕ - ru + pw , \\ \dot{w} = {A}_{z} + g cos θcosϕ - pv + qu ,\end{matrix}$$

which removes mass and forms a set of kinematic equations for all types of aircraft regardless of mass.

FIG. 4a shows a continuous-discrete extended Kalman filter for a stationary system, i.e., F is time-invariant. The input vector, u∈ [symbol] ⁶, includes the IMU measurements in the body frame:

$$u = [ \begin{matrix}{acc}_{x} & {acc}_{y} & {acc}_{z} & {gyro}_{x} & {gyro}_{y} & {gyro}_{z} ]\end{matrix} .$$

The predicted state is defined as:

$$\dot{x} = f ( x ( t ) , u ( t ) , t ) , {\hat{x}}_{k} ( - ) = {\hat{x}}_{k} ( + ) + {\int }_{k - 1}^{k} f ( x ( t ) , u ( t ) , t )$$

with (−) to denote before measurements and k represents the kth iteration. The predicted covariance before measurements is defined as:

$${P}_{k} ( - ) = Φ ( k ) {P}_{k - 1} ( + ) {Φ ( k )}^{T} + Γ ( k ) Q ( k ) {Γ ( k )}^{T}$$

such that with (+) denotes after measurements. Φ(k) and Γ(k) are defined as (Equation 1):

$$Φ ( k ) = {e}^{F ( k ) Δ t} , Γ ( k ) = ( \int Φ ( k ) Δ t ) G ( k )$$

The F (k), G (k), and H (k) matrices are defined as:

$$\begin{matrix}{F ( k ) = \frac{\partial f ( x ) ( t ) , u ( t ) , t )}{\partial x ( t )} \vert}_{x = {\hat{x}}_{k} ( + )} , \\ {G ( k ) = \frac{\partial G ( x ) ( t ) )}{\partial x ( t )} \vert}_{x = {\hat{x}}_{k} ( + )} , \\ {H ( k ) = \frac{\partial h ( f ( x ) ( t ) , u ( t ) , t )}{\partial x ( t )} \vert}_{x = {\hat{x}}_{k} ( + )}\end{matrix}$$

The Kalman gain matrix is:

$${K}_{k} = {P}_{k} ( - ) {{H}_{k}^{T} ( {H}_{k} {P}_{k} ( - ) {H}_{k}^{T} + {R}_{k} )}^{- 1}$$

The state estimate update equation is:

$${\hat{x}}_{k} ( + ) = {\hat{x}}_{k} ( - ) + {K}_{k} ( {z}_{k} - {H}_{k} {\hat{x}}_{k} ( - ) )$$

Using the Joseph stabilized version of the covariance measurement update is a more stable and robust formulation such that it guarantees Pₖ(+) will be symmetric and positive definite if Pₖ(−) is symmetric and positive definite:

$${P}_{k} ( + ) = ( I - {K}_{k} {H}_{k} ) {P}_{k} ( - ) {( I - {K}_{k} {H}_{k} )}^{T} + {K}_{k} {R}_{k} {K}_{k}^{T} .$$

The process and measurement noise covariances are assumed to be constant, diagonal, and utilize the Gaussian distribution, i.e., Q, R˜N[μ, σ²] with u as the mean and σ as the standard deviation. The EKF uses the IMU as the input vector and coplanar POSIT for pose measurements, so Q, R∈ [symbol] ^{6×6}. Thus, the process noise covariance includes uses the IMU measurement variances:

$$Q = diag ⌈ \begin{matrix}{σ}_{acc , x}^{2} & {σ}_{acc , y}^{2} & {σ}_{acc , z}^{2} & {σ}_{gyro , x}^{2} & {σ}_{gyro , y}^{2} & {σ}_{gyro ,}^{2}\end{matrix}$$

The measurement noise covariance utilizes the variances from the coplanar POSIT algorithm:

$$R = diag [ \begin{matrix}{σ}_{N , POSIT}^{2} & {σ}_{E , POSIT}^{2} & {σ}_{U , POSIT}^{2} & {σ}_{ϕ , POSIT}^{2} & {σ}_{θ , POSIT}^{2} & {σ}_{ψ , POSIT}^{2}\end{matrix} ] .$$

FIG. 4a shows the block diagram of an embodiment of EKF 224. The above equations and an embodiment of the invention are further discussed in Kawamura, E. et al., “Vision-Based Precision Approach and Landing for Advanced Air Mobility”, AIAA SCITECH 2022 Forum, published online on Dec. 29, 2021, which is herein incorporated by reference in its entirety. The black box 402 that outputs “c2d” utilizes the functions in Equation (1) above to compute Φ and Γ (406). (c2d stands for continuous to discrete.) The box with “Plant” 404 contains the kinematic equations for predicting the state, \hat{x}(−) 408, before taking measurements. The solid lines between elements in FIG. 4a represent computations for the state, while the dashed lines represent computations for covariance.

FIG. 4b shows the outputs of IMU 226 and COPOSIT 220 as u and y, respectively, which feed into the EKF as the input vector u 228 and measurement vector y 222. The vector u takes accelerometer measurements Aₓ, A_{y}, and A_{z} and gyroscope measurements Φ, θ, Ψ from IMU 226, and the measurement vector y takes the pose estimation (position N,E,U and Euler angles Φ, θ, Ψ) from COPOSIT method 220. The accelerometer and gyroscope measurements in the body frame feed into the input vector u, which feeds into the plant 404 and computations for F and G with white Gaussian noise, w. As shown above, F and G are used to determine Φ and Γ (406.)

FIG. 4c shows another embodiment 480 of the extended Kalman filter of FIG. 2 that does not receive input from the COPOSIT method when input from the COPOSIT method is not available.

With reference to FIG. 4c, at step 482, the measurement input H is zeroed out when the process determines at step 481 that no new IMU/COPOSIT data packet is pending. In this case, with reference to FIG. 4a, in this situation, EKF 224 is run without using the correction element 420. Conventionally, an instruction to skip using data from the COPOSIT method is implemented using a valid/invalid flag that must be set by the COPOSIT and checked for its value by the EKF. Checking a valid/invalid flag takes some processing time but does not significantly increase the system runtime. Instead, defaulting the measurement matrices to all zeroes at times when no COPOSIT output is available saves processing time because zeroing out the measurement matrix H and setting valid/invalid flags are mathematically equivalent. If there is a new IMU/COPOSIT data packet pending 481, at step 486, H is set to identity, and at step 488, EKF 224 is run with prediction and correction elements.

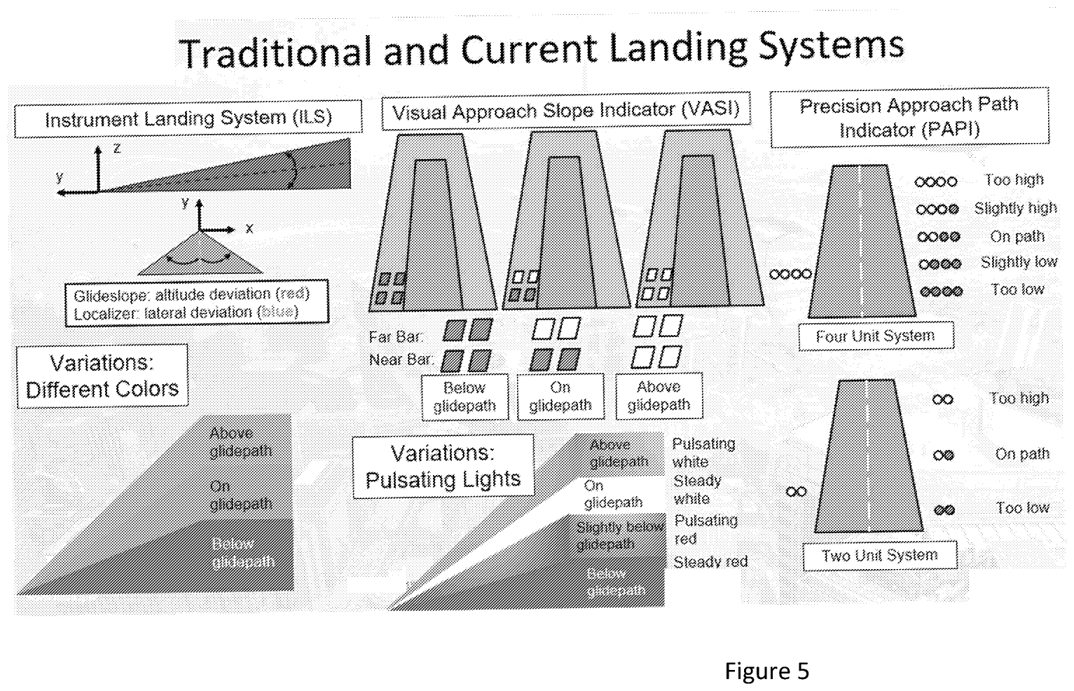

FIG. 5 shows an example of traditional and current landing systems as defined by the Federal Aeronautics Administration (FAA). All of these landing systems provide visual markers that can be detected by present embodiments of the a visual system described herein. In particular, the FAA defines conventional indicators such as color-coded instrument landing system glide slope (G/S) and localizer (LOC), a light-base-coded visual approach slope indicator (VASI), and two versions of a light-based Precision Approach Path indicator (PAPI). Some embodiments of the system described herein further detect and analyze these conventional indicators and utilize the warnings therein as further input to the system. In addition, in the United States, a Ground Based Augmentation System (GBAS) augments the existing Global Positioning System (GPS) used in U.S. airspace by providing corrections to aircraft in the vicinity of an airport in order to improve the accuracy of, and provide integrity for, these aircrafts' GPS navigational position. GBAS generally does not work well in urban environments due to GPS signal degradation.

FIGS. 7a, 7b, and 7c show example results over time from an embodiment of EKF 224 for, respectively, estimates of position, estimates of velocity, and estimates of orientation (i.e., Euler angles). In the implementation of FIG. 7a, estimates of the three position values align closely with the straight lines 702, 704, 706, each of which represents a nominal path. In the implementation of FIG. 7b, estimates of the three velocity values align closely with the straight lines 712, 714, 716, each of which represents a nominal velocity. FIG. 7c shows the aircraft Euler angle camera estimates, Roll Φ (Phi), Pitch θ (Theta), and Yaw Ψ (Psi), which have tiny fluctuations in the roll and pitch angles (see variations around 722 and 724.) In this implementation, there is a positive bias of approximately 0.01 in the pitch angle estimation (above line 724), but the roll angle estimation tends to fluctuate around 0 degrees (above line 722). Overall, the state estimation 230 in this example is fairly accurate due to low mean errors and standard deviations.

FIG. 8 is a block diagram of one embodiment of a computer system that may be used with the present invention. It will be apparent to those of ordinary skill in the art, however other alternative systems of various system architectures may also be used.

The data processing system illustrated in FIG. 8 includes a bus or other internal communication means 840 for communicating information, and a processing unit 810 coupled to the bus 840 for processing information. The processing unit 810 may be a central processing unit (CPU), a digital signal processor (DSP), or another type of processing unit 810.

The system further includes, in one embodiment, a random access memory (RAM) or other volatile storage device 820 (referred to as memory), coupled to bus 840 for storing information and instructions to be executed by processor 810. These instructions perform the methods discussed herein for creating and using Bayesian networks to isolate faults. The memory also stores the Bayesian network. The memory also stores instructions to manage sending and receiving data from the system (such as a quadcopter) and for displaying the user interface discussed herein. Main memory 820 may also be used for storing temporary variables or other intermediate information during execution of instructions by processing unit 810.

The system also comprises in one embodiment non-volatile storage, such as a read only memory (ROM) 850 and/or static storage device coupled to bus 840 for storing static information and instructions for processor 810. In one embodiment, the system also includes a data storage device 830 such as a magnetic disk or optical disk and its corresponding disk drive, or flash memory or other storage which is capable of storing data when no power is supplied to the system. Data storage device 830 in one embodiment is coupled to bus 840 for storing information and instructions.

The system may further be coupled to an output device 870, such as liquid crystal display (LCD) coupled to bus 840 through bus 860 for outputting information. The output device 870 may be a visual output device, an audio output device, and/or tactile output device (e.g., vibrations, etc.)

An input device 875 may be coupled to the bus 860. The input device 875 may be an alphanumeric input device, such as a keyboard including alphanumeric and other keys, for enabling a user to communicate information and command selections to the processing unit 810. An additional user input device 880 may further be included. One such user input device 880 is a cursor control device 880, such as a mouse, a trackball, stylus, cursor direction keys, or touch screen, may be coupled to bus 840 through bus 860 for communicating direction information and command selections to processing unit 810, and for controlling movement on display device 870.

Another device, which may optionally be coupled to computer system 801, is a network device 885 for accessing other nodes of a distributed system via a network. The communication device 885 may include any number of commercially available networking peripheral devices such as those used for coupling to an Ethernet, token ring, Internet, or wide area network, personal area network, wireless network, cellular network, or other method of accessing other devices. The communication device 885 may further be a null-modem connection, or any other mechanism that provides connectivity between the computer system 801 and the outside world.

Note that any or all of the components of this system illustrated in FIG. 8 and associated hardware may be used in various embodiments of the present invention.

It will be appreciated by those of ordinary skill in the art that the particular machine that embodies the present invention may be configured in various ways according to the particular implementation. The control logic or software modules implementing the present invention can be stored in main memory 820, mass storage device 830, or other storage medium locally or remotely accessible to processor 810.

It will be apparent to those of ordinary skill in the art that the system, method, and process described herein can be implemented as software stored in main memory 820 or read only memory 850 and executed by processor 810. This control logic or software modules may also be resident on an article of manufacture comprising a computer readable medium having computer readable program code embodied therein and being readable by the mass storage device 830 and for causing the processor 810 to operate in accordance with the methods and teachings herein.

The present invention may also be embodied in a handheld or portable device containing a subset of the computer hardware components described above. For example, the handheld device may be configured to contain only the bus 840, the processor 810, and memory 850 and/or 820.

The handheld device may be configured to include a set of buttons or input signaling components with which a user may select from a set of available options. These could be considered input device #1 875 or input device #2 880. The handheld device may also be configured to include an output device 870 such as a liquid crystal display (LCD) or display element matrix for displaying information to a user of the handheld device. Conventional methods may be used to implement such a handheld device. The implementation of the present invention for such a device would be apparent to one of ordinary skill in the art given the disclosure of the present invention as provided herein.

The present invention may also be embodied in a special purpose appliance including a subset of the computer hardware components described above, such as a mobile phone, tablet, or a vehicle. For example, the appliance may include a processing unit 810, a data storage device 830, a bus 840, and memory 820, and no input/output mechanisms, or only rudimentary communications mechanisms, such as a small touchscreen that permits the user to communicate in a basic manner with the device. In general, the more special-purpose the device is, the fewer of the elements need be present for the device to function. In some devices, communications with the user may be through a touch-based screen, or similar mechanism. In one embodiment, the device may not provide any direct input/output signals but may be configured and accessed through a website or other network-based connection through network device 885.

It will be appreciated by those of ordinary skill in the art that any configuration of the particular machine implemented as the computer system may be used according to the particular implementation. The control logic or software modules implementing the present invention can be stored on any machine-readable medium locally or remotely accessible to processor 810. A machine-readable medium includes any mechanism for storing information in a form readable by a machine (e.g., a computer). For example, a machine-readable medium includes read-only memory (ROM), random access memory (RAM), magnetic disk storage media, optical storage media, flash memory devices, or other storage media, which may be used for temporary or permanent data storage. In one embodiment, the control logic may be implemented as transmittable data, such as electrical, optical, acoustical or other forms of propagated signals (e.g., carrier waves, infrared signals, digital signals, etc.).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A method of landing an aircraft without usage of a GPS signal, comprising:
receiving an image from a camera attached to an aircraft;
determining a correspondence between estimated landmark locations based on the image and predicted landmark locations to produce a plurality of world coordinates of best matches for at least four coplanar points in the image;
applying a COPOSIT method to the plurality of world coordinates of best matches for the at least four coplanar points to produce an estimated aircraft position and orientation;
receiving, by a Kalman filter, the estimated aircraft position and orientation, and further receiving input from an IMU, the IMU input representing acceleration and angular body rates; and
generating, by the Kalman filter, a state estimation of the aircraft, the state estimation including a corrected estimated position, a corrected estimated velocity, and a corrected estimated orientation of the aircraft, the Kalman filter operating without using input of the GPS signal, the state estimation configured to be outputted to a flight control system of the aircraft for landing the aircraft without using input of the GPS signal.

2. The method of claim 1, further comprising:
detecting features in the image, wherein the features correspond to fiducials; and
estimating the landmark locations based on the detected features; and
predicting the predicted landmark locations.

3. The method of claim 2, wherein the detecting features is performed by Hough circle detection.

4. The method of claim 2, wherein the detecting features is performed by Harris corner detection.

5. The method of claim 1, wherein method is performed by a simulator to simulate aircraft flight using computer-generated terrain and fiducials.

6. The method of claim 1 wherein the aircraft position and orientation are an output measurement matrix of the COPOSIT module, and wherein the output measurement matrix is set to zero when no COPOSIT data is available and the zeroed output measurement matrix is input to the Kalman filter.

7. The method of claim 1, wherein the corrected estimated position, the corrected estimated velocity, and the corrected estimated orientation are repeatedly determined over time based on new received images from the camera and are repeatedly inputted into a flight control system to facilitate landing the aircraft.

8. The method of claim 1, wherein the method is performed in near real time.

9. The method of claim 1, further comprising:
obtaining real world telemetry data and videos from a drone flight test, and
simulating the method using the obtained real world telemetry data and videos as input to the simulation.

10. A system for landing an aircraft without usage of a GPS signal, the system comprising:
a camera attached to an aircraft;
a feature corresponder to determine a correspondence between estimated landmark locations based on the image and predicted landmark locations to produce a plurality of world coordinates of best matches for at least four coplanar points in the image;
a COPOSIT module for applying a COPOSIT method to the plurality of world coordinates of best matches for the at least four coplanar points to produce estimated aircraft position and orientation; and
a Kalman filter that receives the estimated aircraft position and orientation and further receives input from an IMU, the input representing acceleration and angular body rates, the Kalman filter generating a corrected estimated position, a corrected estimated velocity, and a corrected estimated orientation of the aircraft, the Kalman filter operating without using input of the GPS signal, the state estimation configured to be outputted to a flight control system of the aircraft for landing the aircraft without using input of the GPS signal.

11. The system of claim 10,
wherein the determiner further comprises:
detecting features in the image, wherein the features correspond to fiducials, and
estimating the landmark locations based on the detected features; and
a predictor to predict the predicted landmark locations.

12. The system of claim 11, wherein the detecting features is performed by Hough circle detection.

13. The system of claim 12, wherein the detecting features is performed by Harris corner detection.

14. The system of claim 12, wherein method is performed by a simulator to simulate aircraft flight using computer-generated terrain and fiducials.

15. The system of claim 10, wherein the aircraft position and orientation are an output measurement matrix of the COPOSIT module, and wherein the output measurement matrix is set to zero when no COPOSIT data is available and the zeroed output measurement matrix is input to the Kalman filter.

16. The system of claim 10, wherein the corrected estimated position, the corrected estimated velocity, and the corrected estimated orientation are repeatedly determined over time based on new received image from the camera and are repeatedly inputted into a flight control system to facilitate landing the aircraft.

17. The system of claim 10, wherein the system operates in near real time.

18. A computer program product capable for landing an aircraft without usage of a GPS signal, comprising instructions stored in a memory to:
receive an image from a camera attached to an aircraft;
determine a correspondence between estimated landmark locations based on the image and between predicted landmark locations to produce a plurality of world coordinates of best matches for at least four coplanar points in the image;
apply a COPOSIT method to the plurality of world coordinates of best matches for the at least four coplanar points to produce estimated aircraft position and orientation; and
receive, by a Kalman filter, the estimated aircraft position and orientation and further receiving input from an IMU representing acceleration and angular body rates, the Kalman filter generating a state estimation of the aircraft, the state estimation including a corrected estimated position, a corrected estimated velocity, and a corrected estimated orientation of the aircraft, the Kalman filter operating without using input of a GPS signal, the state estimation configured to be outputted to a flight control system of the aircraft for landing the aircraft without using input of the GPS signal.

19. The computer program product of claim 18, further comprising instructions to:
detect features in the image, wherein the features correspond to fiducials, wherein the detecting features is performed by Hough circle detection.

20. The computer program product of claim 18, further comprising instructions to:
detect features in the image, wherein the features correspond to fiducials, wherein the detecting features is performed by Harris corner detection.
